(19) United States
(12) Patent Application Publication
(10) Pub. No.: US 2026/0203455 A1
(43) Pub. Date: Jul. 16, 2026

(54) DISASSEMBLY PROCEDURE MANUAL CREATION DEVICE, DISASSEMBLY PROCEDURE MANUAL CREATION METHOD, AND DISASSEMBLY PROCEDURE MANUAL CREATION SYSTEM

(71) Applicant: Hitachi, Ltd., Tokyo (JP)

(72) Inventor: Makoto ONODERA, Tokyo (JP)

(21) Appl. No.: 19/424,226

(22) Filed: Dec. 18, 2025

(30) Foreign Application Priority Data
Jan. 15, 2025 (JP) 2025-005612

(51) Int. Cl. G06F 30/12; G06F 30/17

(52) U.S. Cl. CPC G06F 30/12; G06F 30/17

(57) ABSTRACT

A disassembly procedure manual creation device includes: a UI control unit that receives information input from a product disassembler and designating a target product to be disassembled; a target product search unit that identifies the target product with reference to a product DB managing product data related to products that may be targets of disassembly, and acquires, from the product DB, the product data corresponding to the identified target product; a disassembly procedure determination unit that determines a disassembly procedure of the target product by calculating, on the basis of CAD data of the target product included in the product data and attribute data of a component constituting the target product, a disassembly path that is a movement route that does not interfere with other components for each component; and a disassembly procedure manual creation unit that creates a disassembly procedure manual on the basis of the determined disassembly procedure.

### CROSS-REFERENCE TO RELATED APPLICATION

The present application claims priority from Japanese application JP2025-005612, filed on January 15, 2025, the content of which is hereby incorporated by reference into this application.

### BACKGROUND

### Technical Field

The present invention relates to a disassembly procedure manual creation device, a disassembly procedure manual creation method, and a disassembly procedure manual creation system.

### Related Art

In the field of product manufacturing, the importance of environmental consideration is increasing, and in particular, reuse of units and components constituting products, reuse of materials, and enabling inspection, repair, and cleaning for extending life are important indices of environmental consideration.

On the other hand, there are various disassembly procedures for reuse of components and the like constituting a product and for cleaning and inspection depending on the purpose of disassembly. For example, a user may voluntarily remove interior components for cleaning the inside of a refrigerator, a maintenance service person may perform replacement of an electronic substrate, replacement of a unit (motor, compressor, camera, or the like), or the like, or a recycler may perform separation of components or the like into plastics, metals, harmful substances, or the like.

In addition, the disassembly procedure varies depending on the presence or absence of an automatic sorter that sorts plastics and metals, a non-ferrous metal sorter, and the like depending on the recycler, and the unit may be re-entrusted to another company, and there are various procedures.

Under such circumstances, it is not realistic for a manufacturer of a product to create a disassembly procedure manual according to all disassembly purposes and provide the disassembly procedure manual in addition to sales of the product. In addition, it is not easy for a maintenance service provider, a recycler, or the like who has to handle a plurality of different products to find a disassembly procedure manual issued by a product manufacturer.

Therefore, it is desired to develop a method for automatically creating a product disassembly procedure. For example, JP 2007-7740 A describes “An automatic procedure manual creation supporting device comprising: a database in which a work element of an assembly procedure and a work element of a disassembly procedure of an electronic device are stored in association with each other; a creation supporting unit that supports creation of an assembly procedure or a disassembly procedure with reference to the work element of the assembly procedure or the work element of the disassembly procedure; and a procedure converting unit that, when the assembly procedure has been created, converts the assembly procedure on the basis of the database to generate a disassembly procedure, and when the disassembly procedure has been created, converts the disassembly procedure on the basis of the database to generate an assembly procedure”.

### SUMMARY

According to the technique described in JP 2007-7740 A, one of the assembly procedure manual and the disassembly procedure manual can be used to automatically create the other. However, in order to generate the disassembly procedure manual, it is necessary to prepare the assembly procedure manual in advance, and when the assembly procedure manual cannot be prepared, the disassembly procedure manual cannot be generated.

The present invention has been made in view of the above points, and an object thereof is to automatically generate a disassembly procedure manual according to the disassembly purpose of the product disassembler such as a user, a maintenance service provider, and a recycler of the product.

The present application includes multiple approaches for solving at least a part of the above problem, and examples thereof are as follows.

In order to solve the above problem, a disassembly procedure manual creation device according to an aspect of the present invention includes: a UI control unit that receives information that is input from a product disassembler and designates a target product to be disassembled; a target product search unit that identifies the target product with reference to a product database (DB) that manages product data related to products that may be targets of disassembly, and acquires, from the product DB, the product data corresponding to the identified target product; a disassembly procedure determination unit that determines a disassembly procedure of the target product on the basis of CAD data of the target product included in the product data and attribute data of a component constituting the target product; and a disassembly procedure manual creation unit that creates a disassembly procedure manual on the basis of the determined disassembly procedure.

According to the present invention, for example, a disassembly procedure manual according to the disassembly purpose of a product disassembler such as a user of the product, a maintenance service provider, and a recycler can be generated automatically.

Problems, configurations, and effects other than those described above will be clarified by the following description of embodiments.

### BRIEF DESCRIPTION OF DRAWINGS

FIG. 1 is a diagram illustrating a configuration example of a disassembly procedure manual creation system according to a first embodiment of the present invention;

FIG. 2 is a diagram illustrating an example of component attribute data;

FIG. 3 is a diagram illustrating a display example of a user interface (UI) screen;

FIG. 4 is a flowchart illustrating an example of product DB registration processing by a disassembly procedure manual creation device;

FIG. 5 is a flowchart illustrating an example of disassembly procedure manual creation processing by the disassembly procedure manual creation device according to the first embodiment;

FIG. 6 is a diagram illustrating a configuration example of a disassembly procedure manual creation system according to a second embodiment of the present invention;

FIG. 7 is a flowchart illustrating an example of disassembly procedure manual creation processing by the disassembly procedure manual creation device according to the second embodiment;

FIG. 8 is a cross-sectional view of an example of a product to be disassembled;

FIG. 9 is a diagram illustrating an example of a disassembly procedure manual;

FIG. 10 is a diagram illustrating an example of the disassembly procedure manual; and

FIG. 11 is a diagram illustrating the example of the disassembly procedure manual.

### DETAILED DESCRIPTION

Hereinafter, a plurality of embodiments of the present invention will be described with reference to the drawings. Each embodiment is an example for describing the present invention, and omission and simplification are appropriately made for clarity of description. The present invention can be implemented in various other forms. Unless otherwise specified, one or a plurality of each component may be provided. In order to facilitate understanding of the invention, positions, sizes, shapes, ranges, and the like of the components illustrated in the drawings may not correspond to their actual positions, sizes, shapes, ranges, and the like. In all the drawings for describing the embodiments, the same members are denoted by the same reference numerals in principle, and repeated description thereof will be omitted. In addition, in the following embodiments, the components (including element steps and the like) are not necessarily essential unless otherwise specified or considered to be obviously essential in principle. In addition, when the terms “formed of A”, “consisting of A”, “having A”, and “including A” are used, other elements are not excluded unless it is specifically stated that only that element is included. Similarly, in the following embodiments, when the shapes, positional relationships, and the like of the components and the like are referred to, the shapes and the like substantially approximate or similar to the shapes and the like are included unless otherwise specified or unless clearly considered not to in principle. In addition, specific examples of “acquisition” at least includes generation, calculation, or reception from the outside performed by the subject.

### Configuration example of disassembly procedure manual creation system 10 according to first embodiment of present invention

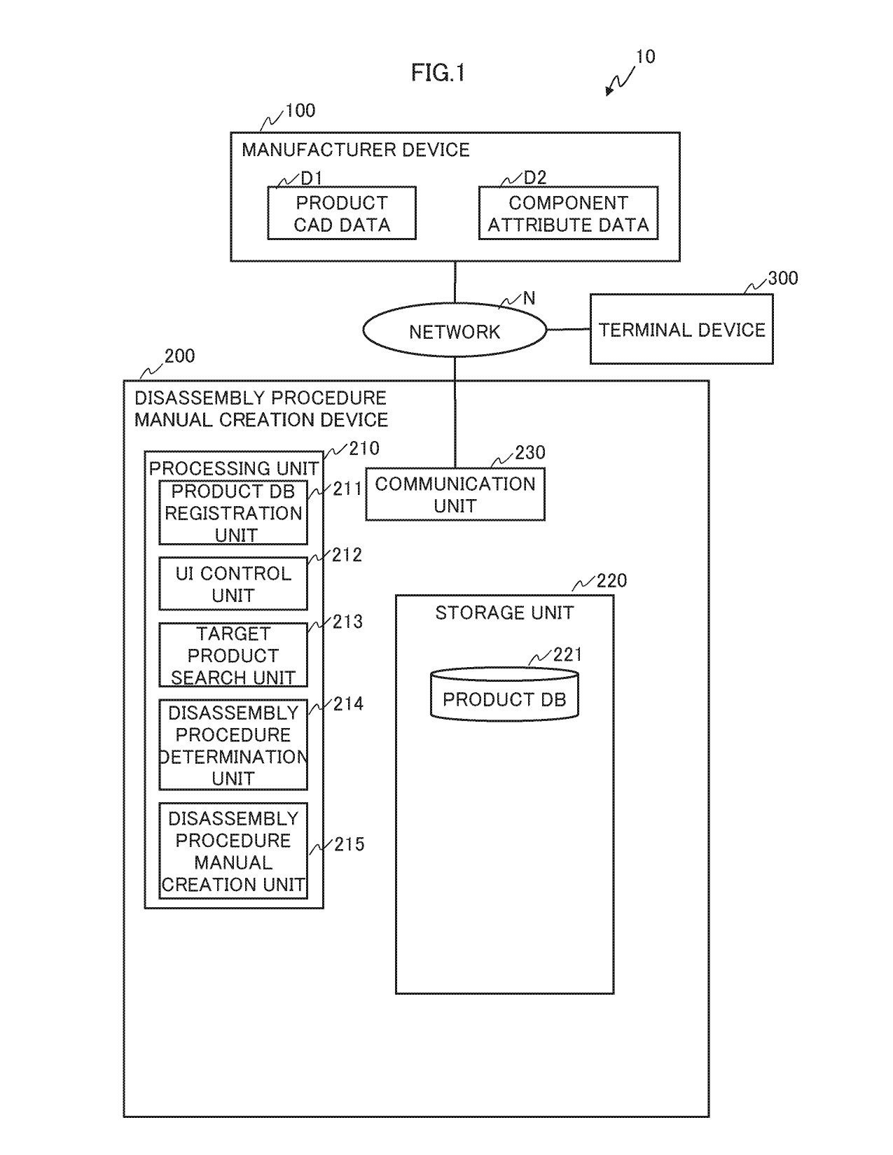

FIG. 1 illustrates a configuration example of a disassembly procedure manual creation system 10 according to a first embodiment of the present invention. The disassembly procedure manual creation system 10 includes a manufacturer device 100, a disassembly procedure manual creation device 200, and a terminal device 300.

The manufacturer device 100 is provided by each manufacturer who manufactures a product. The manufacturer device 100 includes, for example, a general computer such as a server computer. The manufacturer device 100 supplies product computer aided design (CAD) data D1 related to a product that can be a target of disassembly after shipment and operation, and component attribute data D2 representing attributes of components and units (hereinafter collectively referred to as component) constituting the product to the disassembly procedure manual creation device 200 via a network N. The network N is, for example, the Internet.

In the product CAD data D1, the shape of the product and shape data of each component constituting the product are recorded in association with a model number of the product. Shape data includes, for example, B-Reps representation, CSG representation, spatial lattice model representation, and the like, but a representation method thereof is arbitrary. B-Reps representation and CSG representation are representation methods of shape data adopted by many CAD systems. Spatial lattice model representation is a representation method of shape data obtained as a result of laser shape measurement or X-ray CT shape measurement. In addition, in the product CAD data D1, a component number of a component constituting a product is recorded.

Note that in the product CAD data D1, product information useful for product search may be recorded in association with the model number of the product. For example, a Japanese article number (JAN) code, an image (photograph), and the like of the product may be recorded. Note that the product CAD data D1 may include sensitive information that is confidential to a product manufacturer. Therefore, a product DB registration unit 211 may be provided with a function of deleting unnecessary information, information to be kept secret, and the like, which are not related to shape data or attributes of a product, from the product CAD data D1 and registering them in a product DB 221.

In the component attribute data D2, attribute data of each component is recorded in association with a model number of the product and a component number of the component constituting the product. Attribute data includes a material name and material composition information. Furthermore, attribute data may include, for example, an image (photograph) of the component, hazardous/harmful substance information (information indicating whether or not hazardous/harmful substance is contained), disassembly possibility information (information indicating whether or not disassembly into finer components is possible), replacement possibility information (e.g., information such as whether component A may be replaced with new component A or whether component A can be substituted with component B), techniques and tools necessary for disassembly or replacement, and the like. The component attribute data D2 may be included in the product CAD data D1. In some CAD systems, attributes and note information can be included as a 3D annotated model (3DA) or a model based definition (MBD), and thus these pieces of information may be included in the product CAD data D1.

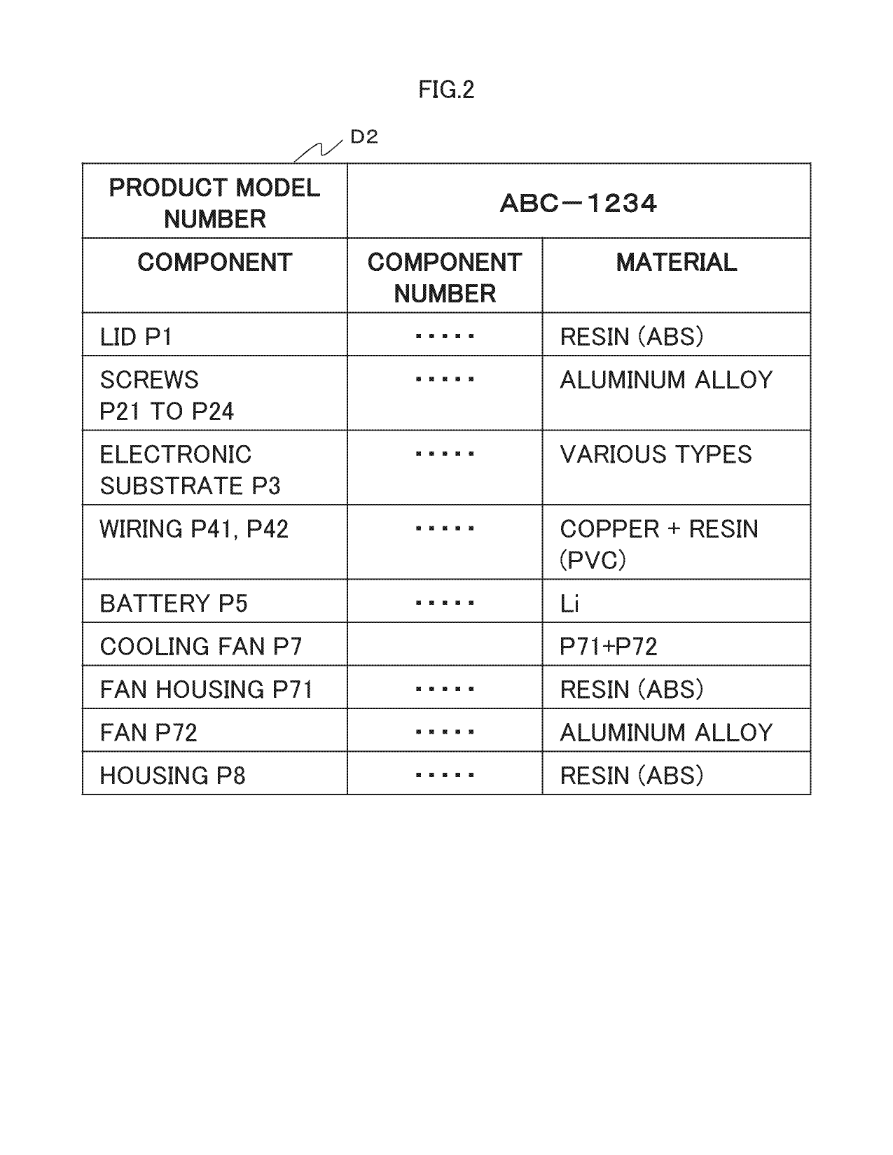

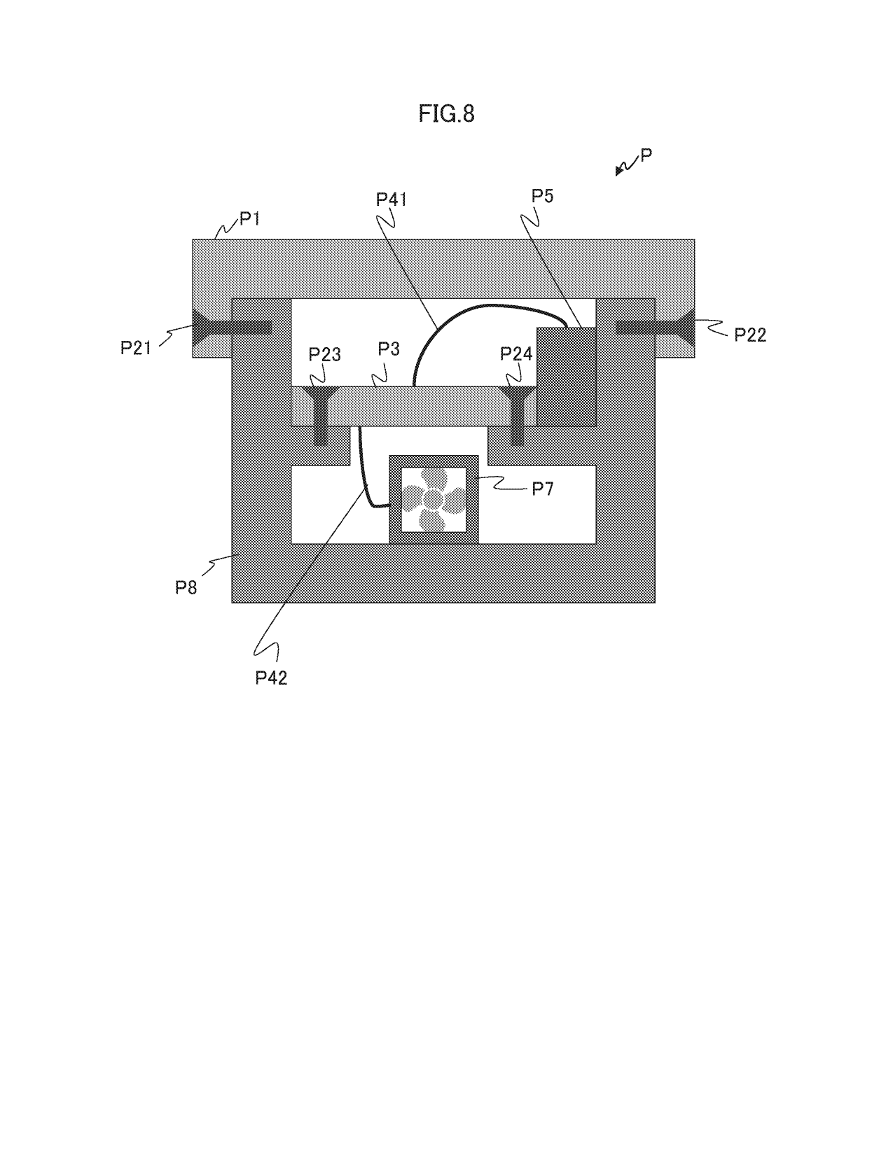

FIG. 2 illustrates the component attribute data D2 corresponding to a product P (FIG. 8) as an example of the component attribute data D2. In the example of FIG. 2, it is recorded that the product P of model number ABC-1234 includes a lid P1, screws P21 to P24, an electronic substrate P3, and the like, the material of the lid P1 is resin (ABS), and the material of the screws P21 to P24 is an aluminum alloy.

The disassembly procedure manual creation device 200 is implemented by, for example, a general computer such as a personal computer or a server computer. The computer includes a processor such as a central processing unit (CPU), a memory such as a dynamic random access memory (DRAM), a storage such as a hard disk drive (HDD) or a solid state drive (SSD), an input device such as a keyboard, a mouse, and a media drive, an output device such as a display, and a communication module such as an Ethernet (trademark) card or a Wi-Fi (trademark) adapter.

The disassembly procedure manual creation device 200 may be implemented by one physical or logical computer, or may be implemented by two or more physical or logical computers. The two or more physical or logical computers may be arranged on the network N in a distributed manner.

The disassembly procedure manual creation device 200 includes functional blocks of a processing unit 210, a storage unit 220, and a communication unit 230.

The processing unit 210 is implemented by a processor of the computer. The processing unit 210 controls the entire disassembly procedure manual creation device 200. The processing unit 210 implements the functional blocks of the product DB registration unit 211, a UI control unit 212, a target product search unit 213, a disassembly procedure determination unit 214, and a disassembly procedure manual creation unit 215 by executing a program (not illustrated) stored in the storage unit 220.

The product DB registration unit 211 acquires the product CAD data D1 and the component attribute data D2 from the manufacturer device 100 via the network N, and registers the product CAD data D1 and the component attribute data D2 as product data in the product DB 221 of the storage unit 220.

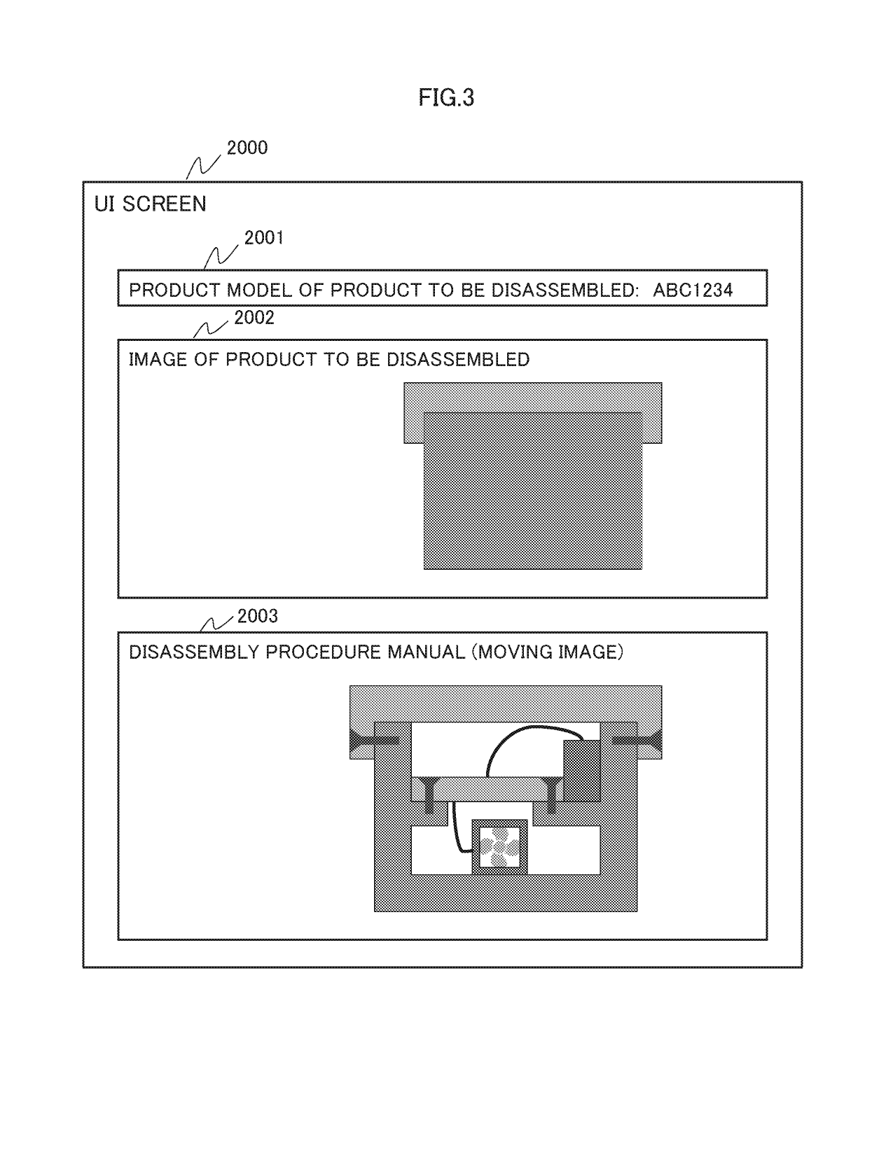

The UI control unit 212 displays a UI screen 2000 (FIG. 3) on the terminal device 300 connected via the network N, and receives various inputs from the user of the terminal device 300 to the UI screen 2000. In addition, the UI control unit 212 causes the UI screen 2000 to display a disassembly procedure manual created by the disassembly procedure manual creation unit 215. Note that the terminal device 300 is used by a product disassembler who disassembles a product as the user, and is configured to receive input, for example, of a model number, a product image, and the like of a product to be disassembled (hereinafter referred to as target product) (to be described in detail later).

The target product search unit 213 refers to the product DB 221 on the basis of the model number and the product image of the target product input to the UI screen 2000, identifies the target product, and acquires the product CAD data D1 and the component attribute data D2 regarding the identified target product from the product DB 221.

The disassembly procedure determination unit 214 determines a disassembly procedure of the target product on the basis of the product CAD data D1 and the component attribute data D2 related to the target product.

Specifically, the disassembly procedure determination unit 214 recognizes a joint portion between components by rivet-type fasteners such as screws, bolts, and rivets, and a joint portion between components by non-fasteners such as snap-fit, adhesion, and welding. In this recognition, the joined components are also recognized. Note that as a method of recognizing the joint portion, for example, a partial similar shape search technique (Reference: Makoto Onodera et al., Development of mesh generation technique reusing proven analysis models by similar sub-part search, Transactions of the Japan Society of Mechanical Engineers (JSME), Vol. 83, No. 853, DOI: 10.1299/transjsme. 17-00073.), which is an existing similar shape search technique, can be used. In the similar shape search technique, the area, the peripheral length, the surface type, the curvature, and the main direction length of the surface are used as a geometric feature amount, and the connection relationship between the surfaces is used as a topological feature amount to calculate the similarity. By preparing shapes of a screw, a bolt, and a snap-fit in advance, a shape similar thereto can be recognized as a joint portion. In addition, a method may be used in which a target shape is expressed by a voxel structure, a block is defined by several adjacent voxels, spectrum calculation is performed for each block, and similarity is calculated. The joint portion is recognized using these methods.

Next, the disassembly procedure determination unit 214 calculates a disassembly path, which is a movement path for separating each component constituting the product without interfering with other components. The disassembly procedure determination unit 214 determines that a component whose movement path (disassembly path) cannot be calculated is a component that cannot be disassembled at that time, calculates a disassembly path of another component, and then calculates the disassembly path again. By repeating this, the disassembly path of each component is calculated. Note that an evaluation formula for ease of disassembly and the like may be introduced into the disassembly path, and optimization may be performed to facilitate disassembly. Here, ease of disassembly is used to evaluate how long (short) the disassembly path is, the space volume (when volume is large, there is little possibility of contact with other components, and there is sufficient space for inserting hand or tool) around the disassembly path, the presence or absence of a necessary tool (snap fitting does not require tool, screws and bolts require tool such as screwdriver, bonded portion requires application of heat, welded portion requires use of cutting tool, for example), and the like. Note that for a component requiring a special tool or disassembly procedure, it is desirable to register information indicating the fact in the component attribute data D2.

Furthermore, the disassembly procedure determination unit 214 refers to the disassembly possibility information of the component attribute data D2, and does not create a disassembly procedure for a component that cannot be disassembled. For example, in a case where the disassembly possibility information of a motor as a component is “non-disassemblable”, although the motor includes components such as a magnet, a coil, and a stator, the disassembly is stopped at the unit of the motor, and the motor is not disassembled into the magnet, the coil, the stator, and the like. Alternatively, information indicating that a component is only disassemblable by a product disassembler having special skills may be included in the disassembly possibility information. In this case, the disassembly path of the motor as a component is calculated, but the disassembly path of the magnet, the coil, the stator, and the like is not calculated. Similarly, the disassembly procedure determination unit 214 refers to the danger/harmful substance information of the component attribute data D2, and does not calculate the disassembly path for a component containing hazardous/harmful substances.

The disassembly procedure manual creation unit 215 creates a disassembly procedure manual as a moving image (animation), for example, on the basis of the recognized joint portions and the calculated disassembly paths of the component. The disassembly procedure manual may be a plurality of still images. The created disassembly procedure manual is displayed on the UI screen 2000.

The storage unit 220 is implemented by a memory and a storage of the computer. The storage unit 220 stores programs, various DBs, and the like.

The communication unit 230 is implemented by a communication module of the computer. The communication unit 230 is connected to the manufacturer device 100 and the terminal device 300 via the network N, and communicates various data, information, and the like.

The terminal device 300 is used by, for example, disassemblers (hereinafter collectively referred to as product disassemblers) who disassemble a product according to a certain disassembly purpose such as a user of the product, a maintenance service person, a recycler, and the like. The terminal device 300 includes, for example, a general computer such as a personal computer, a tablet computer, or a smartphone. The terminal device 300 is connected to the disassembly procedure manual creation device 200 via the network N by executing a general-purpose browser or a dedicated application program, and displays the UI screen 2000 under the control of the UI control unit 212.

FIG. 3 illustrates a display example of the UI screen 2000. The UI screen 2000 is provided with an input field 2001 for the product disassembler to input a model number of a product to be disassembled, an input field 2002 for the product disassembler to input an image (photograph) obtained by imaging the product, and a display field 2003 for displaying the created disassembly procedure manual.

### Product DB registration processing

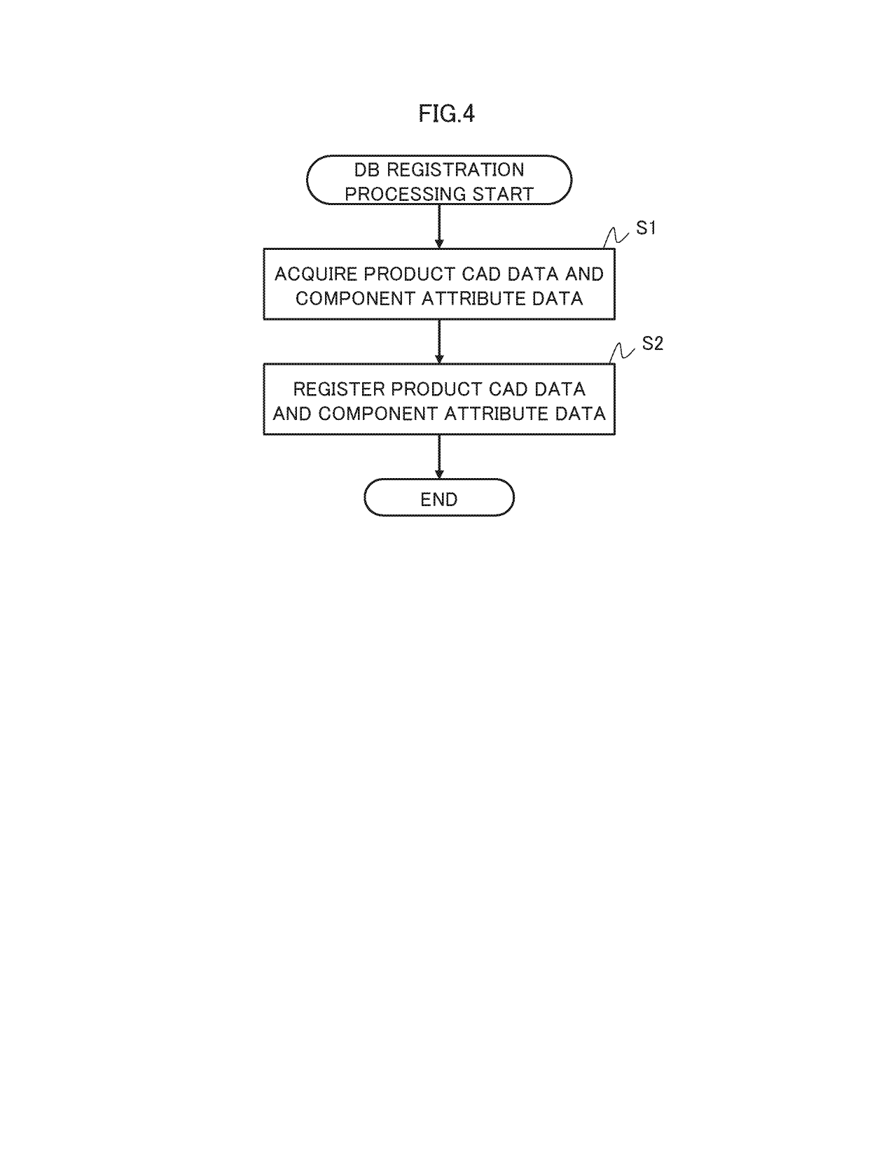

FIG. 4 is a flowchart illustrating an example of product DB registration processing.

The product DB registration processing is periodically executed at a predetermined cycle such as once every half year, for example.

First, the product DB registration unit 211 connects to the manufacturer device 100 via the communication unit 230 and the network N, and acquires the product CAD data D1 and the component attribute data D2 related to a product whose sale has been started or whose specification has been changed from the previous execution timing to the current execution timing of the product DB registration processing (step S1). Next, the product DB registration unit 211 registers the acquired product CAD data D1 and component attribute data D2 in the product DB 221 (step S2). Hereinabove, the product DB registration processing has been described.

### Disassembly procedure manual creation processing by disassembly procedure manual creation device 200 according to first embodiment

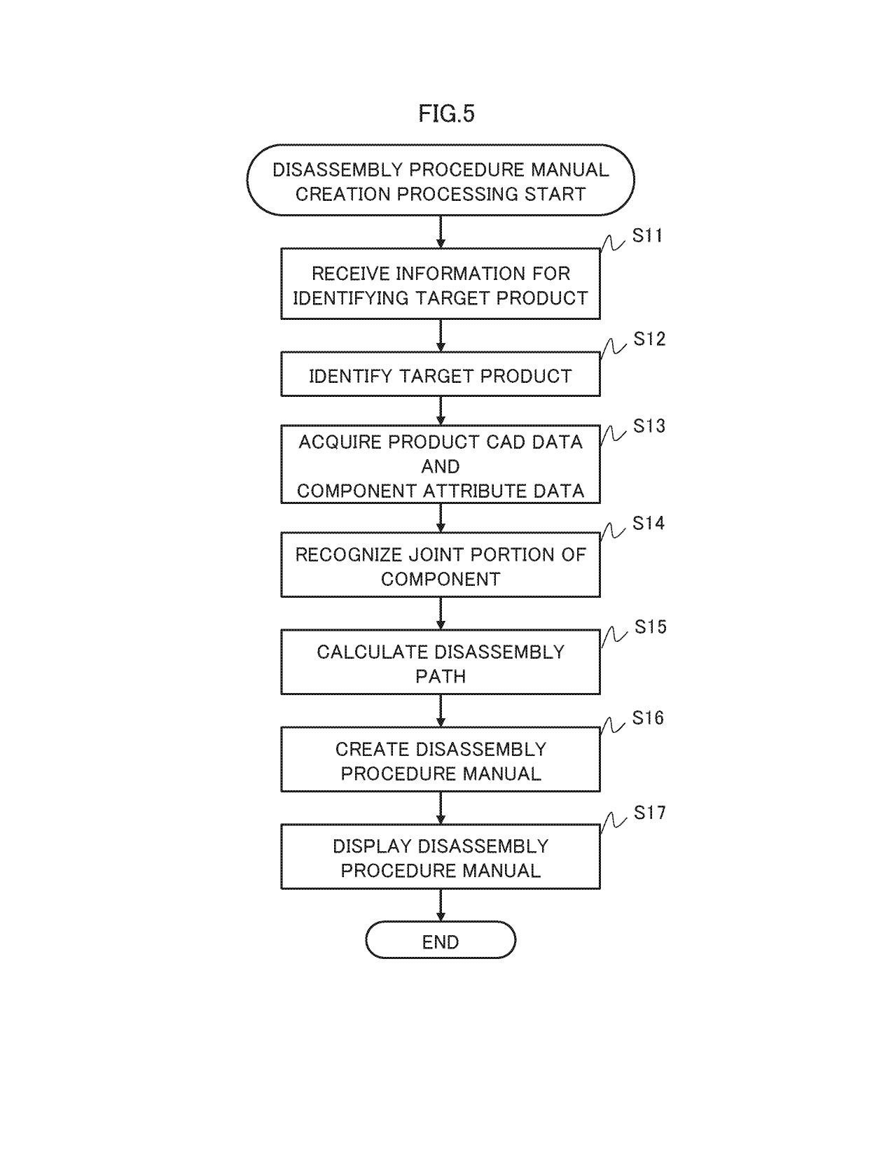

FIG. 5 is a flowchart illustrating an example of disassembly procedure manual creation processing by the disassembly procedure manual creation device 200 according to the first embodiment.

The disassembly procedure manual creation processing is started, for example, in response to a predetermined operation from the product disassembler who accesses the disassembly procedure manual creation device 200 using the terminal device 300.

First, the UI control unit 212 causes the terminal device 300 to display the UI screen 2000 (FIG. 3), and receives information (at least one of model number of product and product image) for identifying the target product input to the input fields 2001 and 2002 of the UI screen 2000 by the product disassembler (step S11).

Next, the target product search unit 213 identifies the target product with reference to the product DB 221 on the basis of at least one of the model number and the product image of the target product input to the UI screen 2000 (step S12). Next, the target product search unit 213 acquires the product CAD data D1 and the component attribute data D2 related to the identified target product from the product DB 221 (step S13).

Next, the disassembly procedure determination unit 214 recognizes a joint portion between components in the target product, and also recognizes joined components (step S14). Next, the disassembly procedure determination unit 214 calculates a disassembly path for each component of the target product (step S15).

Next, the disassembly procedure manual creation unit 215 creates a disassembly procedure manual on the basis of the joint portion recognized and the disassembly paths of the components calculated by the disassembly procedure determination unit 214 (step S16). Next, the UI control unit 212 presents the disassembly procedure manual created by the disassembly procedure manual creation unit 215 to the product disassembler by displaying the disassembly procedure manual in the display field 2003 of the UI screen 2000 displayed on the terminal device 300 (step S17). Hereinabove, the disassembly procedure manual creation processing according to the first embodiment has been described.

According to the present embodiment, the product disassembler can obtain a disassembly procedure manual for the target product by inputting at least one of the model number of the target product and an image (photograph) of the target product.

### Configuration example of disassembly procedure manual creation system 20 according to second embodiment of present invention

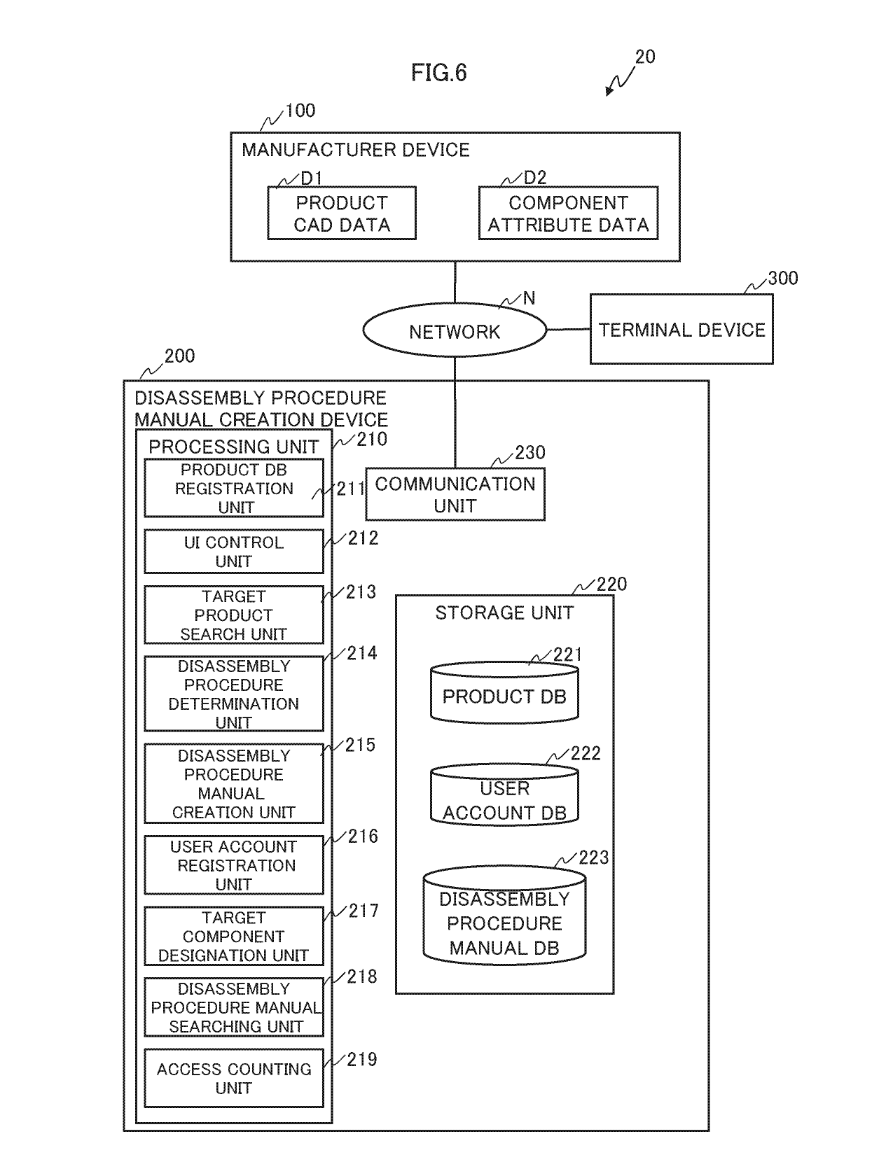

FIG. 6 illustrates a configuration example of a disassembly procedure manual creation system 20 according to a second embodiment of the present invention. The disassembly procedure manual creation system 20 is obtained by adding a user account registration unit 216, a target component designation unit 217, a disassembly procedure manual searching unit 218, and an access counting unit 219 to the processing unit 210, and adding a user account DB 222 and a disassembly procedure manual DB 223 to the storage unit 220 in the disassembly procedure manual creation device 200 of the disassembly procedure manual creation system 10 (FIG. 1).

Among the components of the disassembly procedure manual creation system 20, components common to the components of the disassembly procedure manual creation system 10 (FIG. 1) are denoted by the same reference numerals, and the description thereof will be omitted.

The user account registration unit 216 registers, in the user account DB 222, account information of the product disassembler input by the product disassembler who is the user of the disassembly procedure manual creation system 20 using a terminal device 300 and received by a UI control unit 212. Account information of a user includes, for example, a type of the product disassembler, a qualification held by the product disassembler, mixed materials that can be handled, an allowable ratio of different materials, and the like in a case where the product disassembler is a recycler, in association with the identification information of the product disassembler.

The type of the product disassembler is information indicating whether the product disassembler is a user of the product, a maintenance service person, a recycler, or the like. Note that a product manufacturer (manufacturer) may be registered as the type of the product disassembler. In this case, usage for a product manufacturer to quantitatively evaluate ease of disassembly at a design stage, usage for planning and designing a product life cycle for achieving circular economy, and the like are assumed. The qualification held by the product disassembler is, for example, a hazardous material handler, an electrician, or the like.

For example, when the product disassembler is a recycler and has a plastic and metal sorter, plastic and metal can be designated as mixed materials. Similarly, when the product disassembler has a non-ferrous metal sorter, a steel-based material and an aluminum alloy-based material can be designated as mixed materials. In this case, the disassembly procedure manual creation unit 215 creates the disassembly procedure manual so that the plastic and the metal, and the steel-based material and the aluminum alloy-based material can be taken out as one lump without being disassembled.

In addition, for example, in a case where the product disassembler has an electrician qualification, the target component designation unit 217 (to be described later) can designate, as the target component, a component (including unit) for which the electrician qualification grants qualification (technique) to disassemble in component attribute data D2. In other words, when the product disassembler does not have an electrician qualification, the target component designation unit 217 (described later) cannot designate the component as a target component.

In addition, for example, when it is registered that the allowable ratio of different materials of copper and resin is 10% as the attribute information of the product disassembler, a disassembly procedure manual creation unit 215 creates the disassembly procedure manual so that, for example, wiring in which a copper wire is covered with resin can be taken out as one lump without being disassembled into copper and resin. In addition, when the allowable ratio of different materials is registered to be 0%, the disassembly procedure manual creation unit 215 creates the disassembly procedure manual so that the wiring is disassembled into the copper wire and the coated resin.

The target component designation unit 217 designates a component (target component) to be removed from the target product in accordance with an input from the product disassembler. In this case, a UI screen 2000 is provided with an input field for inputting information (component number, image (photograph) of component, and the like) for identifying the target component. That is, a user or a maintenance provider as a product disassembler rarely disassembles the entire product, and the purpose of disassembly is often to take out a specific component. For example, when the target product is a stick type cleaner, the purpose of disassembly is often to take out and discard a battery or to take out and replace a filter. In such a case, the target component designation unit 217 designates the battery or the filter as the target component. In response to this designation, the disassembly procedure manual creation unit 215 creates the disassembly procedure manual up to removal of the target component.

The disassembly procedure manual searching unit 218 searches for the disassembly procedure manual created by the disassembly procedure manual creation unit 215 in the past and registered in the disassembly procedure manual DB 223 (described later). Since the disassembly procedure manual searching unit 218 and the disassembly procedure manual DB 223 are provided, it is not necessary to generate a disassembly procedure manual again for a target product and a target component for which the disassembly procedure manual has been created in the past, so that the calculation cost of a disassembly procedure manual creation device 200 can be suppressed.

The access counting unit 219 counts the number of times and frequency of creating the disassembly procedure manual for each product or component registered in the product DB 221, and registers the count result in a product DB 221. These count results are assumed to be used for improvement such as designing a structure with higher ease of disassembly in the next product, for example, because products and components whose disassembly procedure manual is repeatedly and frequently created have high disassembly needs.

The user account DB 222 manages account information of the product disassembler registered by the user account registration unit 216.

The disassembly procedure manual DB 223 manages the disassembly procedure manual created by the disassembly procedure manual creation unit 215. Note that the disassembly procedure manual managed in the disassembly procedure manual DB 223 may be disclosed via, for example, a network N. In this case, shipping may be performed by printing access information (uniform resource locator (URL), QR code (trademark), or the like) for accessing the disassembly procedure manual on an instruction manual of the target product, or attaching a printed label or the like to the target product.

### Disassembly procedure manual creation processing by disassembly procedure manual creation device 200 according to second embodiment

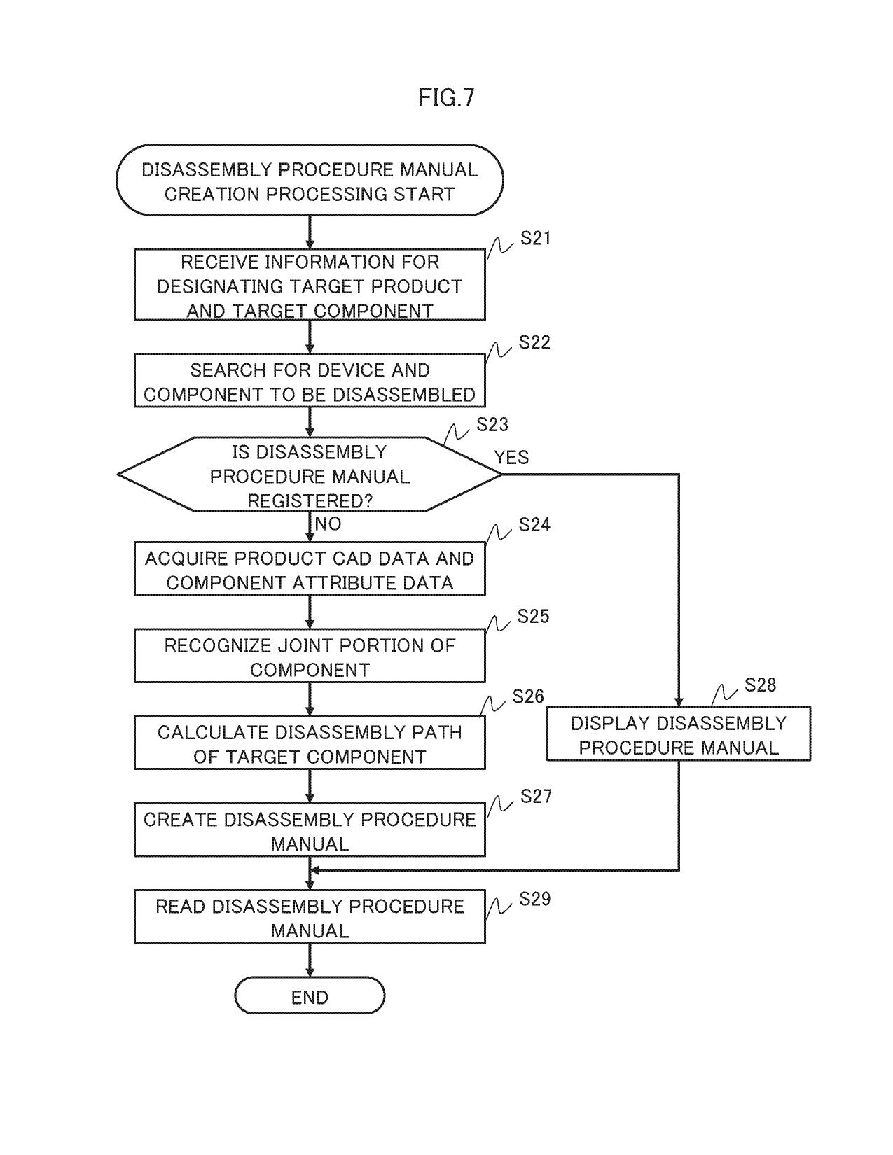

FIG. 7 is a flowchart illustrating an example of disassembly procedure manual creation processing by the disassembly procedure manual creation device 200 according to the second embodiment.

The disassembly procedure manual creation processing is started, for example, in response to a predetermined operation from the product disassembler who accesses the disassembly procedure manual creation device 200 using the terminal device 300.

First, the UI control unit 212 displays the UI screen 2000 (FIG. 3) on the terminal device 300, and receives information for identifying the target product and information for identifying the target component input by the product disassembler (step S21).

Next, a target product search unit 213 identifies the target product with reference to the product DB 221 on the basis of the information for identifying the target product input to the UI screen 2000. In addition, the target component designation unit 217 identifies the target component with reference to the product DB 221 on the basis of the information for identifying the target component input to the UI screen 2000 (step S22).

Next, the disassembly procedure manual searching unit 218 refers to the disassembly procedure manual DB 223 and determines whether or not a disassembly procedure manual corresponding to the target product and the target component identified in step S22 has been registered in the disassembly procedure manual DB 223 (step S23). Here, if it is determined that the disassembly procedure manual has not been registered in the disassembly procedure manual DB 223 (NO in step S23), next, the target product search unit 213 acquires product CAD data D1 and the component attribute data D2 related to the identified target product from the product DB 221 (step S24).

Next, a disassembly procedure determination unit 214 recognizes a joint portion between components in the target product and also recognizes joined components (step S25), and calculates a disassembly path for the target component of the target product (step S26).

Next, the disassembly procedure manual creation unit 215 creates a disassembly procedure manual on the basis of the joint portion and the disassembly path of the target component recognized and calculated by the disassembly procedure determination unit 214 (step S27). Next, the UI control unit 212 presents the disassembly procedure manual created by the disassembly procedure manual creation unit 215 to the product disassembler by displaying the disassembly procedure manual in the display field 2003 of the UI screen 2000 displayed on the terminal device 300 (step S29).

Note that if it is determined in step S23 that a disassembly procedure manual corresponding to the target product and the target component identified in step S22 has been registered in the disassembly procedure manual DB 223 (YES in step S23), next, the disassembly procedure manual searching unit 218 reads the disassembly procedure manual from the disassembly procedure manual DB 223 (step S28). Thereafter, the processing proceeds to step S29, and the disassembly procedure manual corresponding to the target product and the target component is presented to the product disassembler. Hereinabove, the disassembly procedure manual creation processing according to the second embodiment has been described.

According to the present embodiment, the product disassembler can obtain a disassembly procedure manual for taking out a target component of a target product.

### Example of disassembly procedure manual

Next, an example of the disassembly procedure manual will be described.

FIG. 8 is a cross-sectional view of an example of a target product P. The target product P includes components such as a lid P1, screws P21 to P24, an electronic substrate P3, wirings P41 and P42, a battery P5, a cooling fan P7, and a housing P8.

The lid P1 is joined to the housing P8 by the screws P21 and P22. The electronic substrate P3 is joined to an upper stage inside the housing P8 by the screws P23 and P24. The battery P5 is arranged on the upper stage inside the housing P8, and supplies power to the electronic substrate P3 via the wiring P41. The cooling fan P7 is arranged on a lower stage inside the housing P8, and is connected to the electronic substrate P3 via the wiring P42.

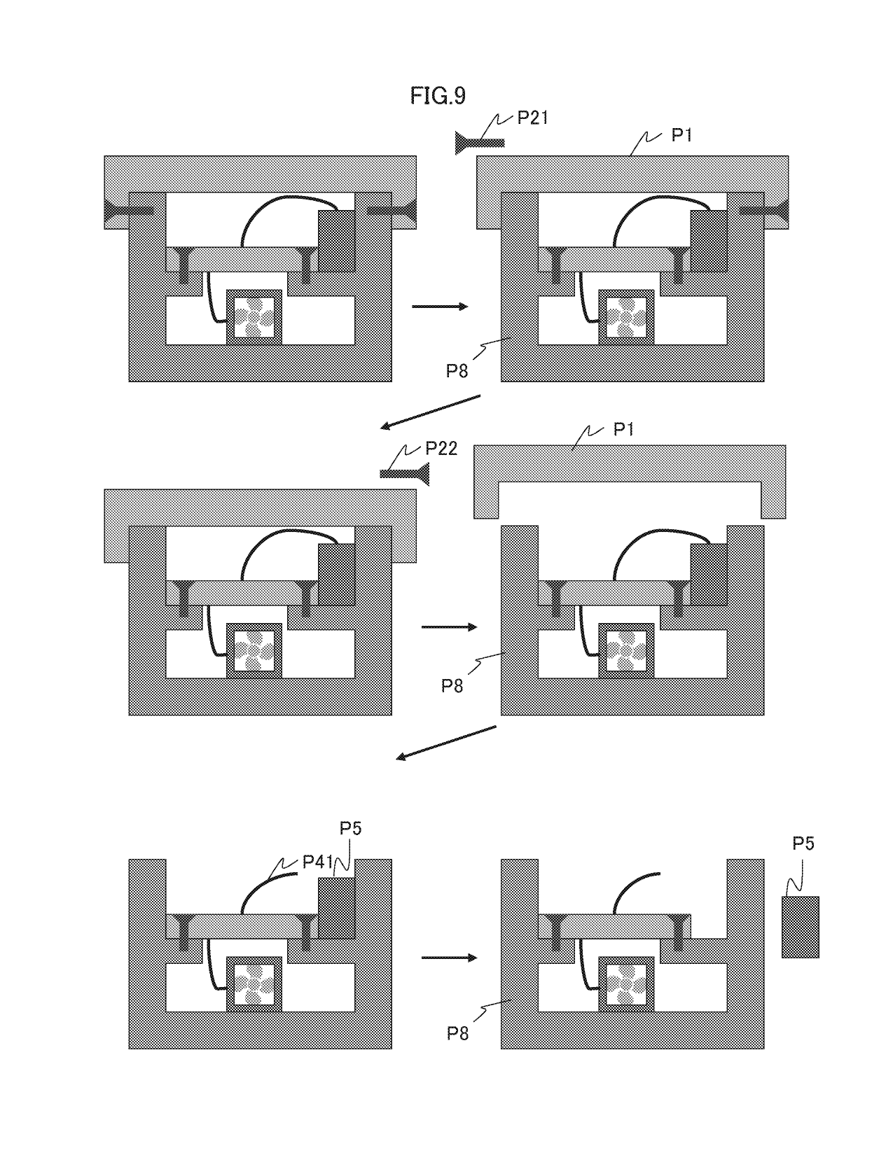

FIG. 9 illustrates an example of a disassembly procedure manual corresponding to a use case where a user of the product removes the battery P5 from the target product P and disposes of the battery P5, for example.

In this use case, the user as a product disassembler designates the target product and the target component (battery P5). In this case, a disassembly procedure manual up to removal of the battery P5 is created.

The upper left part of FIG. 9 illustrates a state before disassembly. First, as illustrated in the upper right part of FIG. 9, the screw P21 joining the lid P1 to the housing P8 is removed. Next, as illustrated in the middle left part of FIG. 9, the screw P22 is removed. Next, as illustrated in the middle right part of FIG. 9, the lid P1 is removed from the housing P8. Next, as illustrated in the lower left part of FIG. 9, the wiring P41 is removed from the battery P5. Finally, the battery P5 is taken out of the housing P8. The disassembly procedure manual up to removal of the battery P5 has been described above.

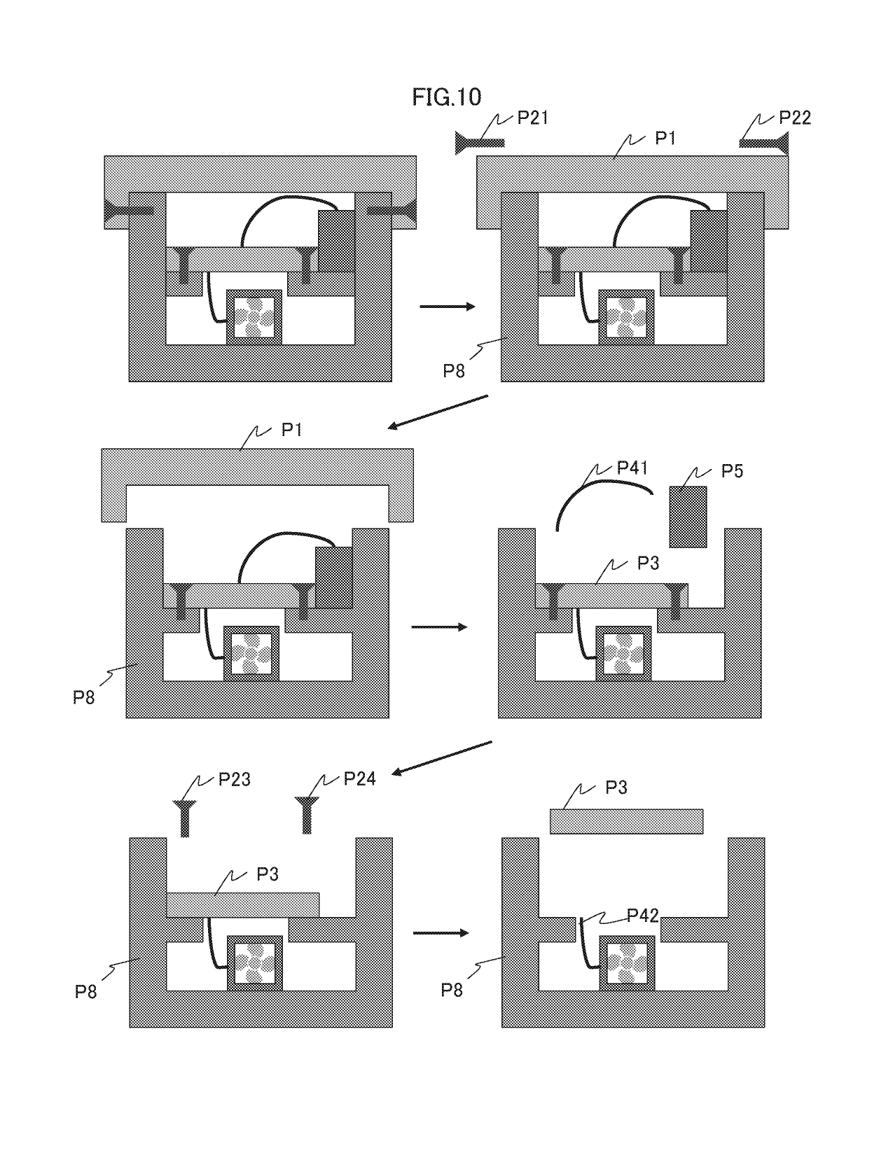

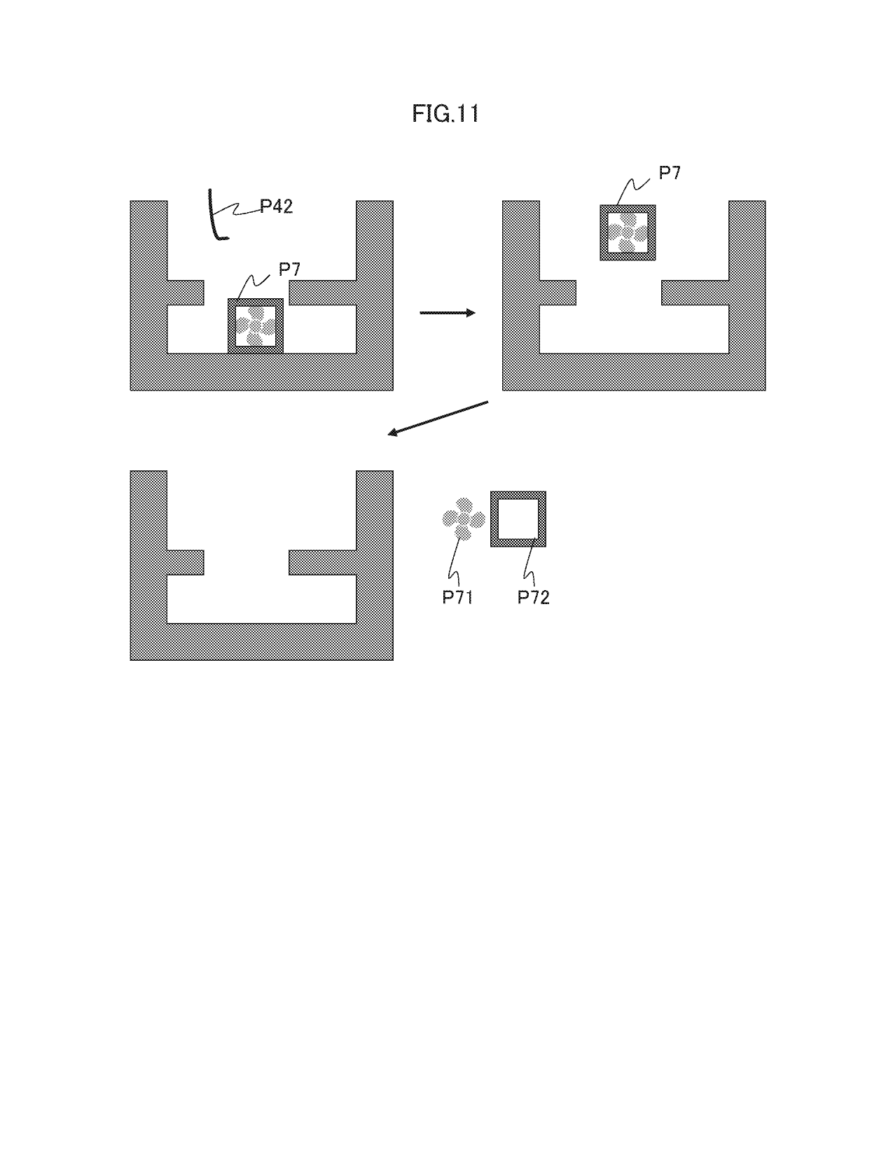

Next, FIGS. 10 and 11 illustrate an example of a disassembly procedure manual corresponding to a use case where, for example, a recycler as a product disassembler does not have a sorter for resin (plastic) and metal, and an allowable ratio of different materials is 10% or less (resin and metal may be mixed up to 10%).

In this use case, the recycler as a product disassembler designates the target product. In this case, a disassembly procedure manual for disassembling a component containing resin and metal into resin and metal is created.

The upper left part of FIG. 10 illustrates a state before disassembly. First, as illustrated in the upper right part of FIG. 10, the screws P21 and P22 joining the lid P1 to the housing P8 are removed. Next, as illustrated in the middle left part of FIG. 10, the lid P1 is removed from the housing P8. Next, as illustrated in the middle right part of FIG. 10, the wiring P41 connected to the electronic substrate P3, and the battery P5 are removed. Next, as illustrated in the lower left part of FIG. 10, the screws P23 and P24 joining the electronic substrate P3 to the inside of the housing P8 are removed. Next, as illustrated in the lower right part of FIG. 10, the electronic substrate P3 is removed from the housing P8, and the wiring P42 is removed from the electronic substrate P3.

Next, as illustrated in the upper left part of FIG. 11, the wiring P42 is removed from the cooling fan P7. Next, as illustrated in the upper right part of FIG. 11, the cooling fan P7 is taken out of the housing P8. Finally, as illustrated in the lower left part of FIG. 11, the cooling fan P7 is separated into a fan P71 made of an aluminum alloy and a fan housing P72 made of resin. The disassembly procedure manual up to disassembly of the component including resin and metal into resin and metal has been described above.

As described above, according to the embodiments of the present invention, it is possible to create a disassembly procedure manual according to the disassembly purpose of the product disassembler and present the disassembly procedure manual to the product disassembler.

The present invention is not limited to the above-described embodiments, and various modifications are possible. For example, the above-described embodiments have been described in detail for easy understanding of the present invention, but the invention is not necessarily limited to having all the described configurations. In addition, a part of the configuration of one embodiment can be replaced with or added to the configuration of another embodiment.

What is claimed is:

1. A disassembly procedure manual creation device comprising:
a UI control unit configured to receive information that is input from a product disassembler and designates a target product to be disassembled;
a target product search unit configured to identify the target product with reference to a product database (DB) that manages product data related to products that may be targets of disassembly, and acquire, from the product DB, the product data corresponding to the identified target product;
a disassembly procedure determination unit configured to determine a disassembly procedure of the target product by calculating, on the basis of CAD data of the target product included in the product data and attribute data of a component constituting the target product, a disassembly path that is a movement route that does not interfere with other components for each component; and
a disassembly procedure manual creation unit that creates a disassembly procedure manual on the basis of the determined disassembly procedure.

2. The disassembly procedure manual creation device according to claim 1, wherein
the disassembly procedure determination unit recognizes a joint portion between components constituting the target product and the joined components, and calculates the disassembly path of the component.

3. The disassembly procedure manual creation device according to claim 1, wherein
the disassembly procedure determination unit calculates, for the component for which the disassembly path cannot be calculated, the disassembly path of another component and then calculates the disassembly path again.

4. The disassembly procedure manual creation device according to claim 1, wherein
the disassembly procedure determination unit calculates the optimum disassembly path by evaluating ease of disassembly for each of the components.

5. The disassembly procedure manual creation device according to claim 1, wherein
the UI control unit receives information that is input from the product disassembler and designates a component to be removed from the target product, and
the disassembly procedure manual creation unit creates the disassembly procedure manual up to removal of the component to be removed from the target product.

6. The disassembly procedure manual creation device according to claim 1, wherein
the disassembly procedure manual creation unit refers to a user account DB in which account information of the product disassembler is registered, and creates the disassembly procedure manual according to the account information of the product disassembler.

7. The disassembly procedure manual creation device according to claim 1, wherein
the disassembly procedure manual creation unit refers to a user account DB in which account information of the product disassembler is registered, and creates the disassembly procedure manual according to the account information of the product disassembler and the attribute data of the target product.

8. The disassembly procedure manual creation device according to claim 6, wherein
the account information of the product disassembler includes at least one of a type of the product disassembler, a qualification held, mixed materials that can be handled by the product disassembler, and an allowable ratio of different materials.

9. The disassembly procedure manual creation device according to claim 1, further comprising:
a disassembly procedure manual DB configured to manage the disassembly procedure manual created by the disassembly procedure manual creation unit; and
a disassembly procedure manual searching unit configured to search for the disassembly procedure manual registered in the disassembly procedure manual DB.

10. The disassembly procedure manual creation device according to claim 9, wherein
access information for the disassembly procedure manual registered in the disassembly procedure manual DB is disclosed in association with a product corresponding to the disassembly procedure manual.

11. The disassembly procedure manual creation device according to claim 1, further comprising
an access counting unit configured to count at least one of the number of times and a frequency of creating the disassembly procedure manual for the product whose product data is registered in the product DB.

12. The disassembly procedure manual creation device according to claim 1, further comprising
a product DB registration unit configured to acquire CAD data related to a product that can be a target of disassembly and attribute data of a component, and register the CAD data and the attribute data in the product DB as the product data, wherein
the product DB registration unit excludes unnecessary information not related to the product and information to be kept secret from the CAD data and the attribute data and registers the information in the product DB.

13. A disassembly procedure manual creation method of a disassembly procedure manual creation device, the method comprising:
a reception step of receiving information that is input from a product disassembler and designates a target product to be disassembled;
a target product search step of identifying the target product with reference to a product DB that manages product data related to products that may be targets of disassembly, and acquiring, from the product DB, the product data corresponding to the identified target product;
a disassembly procedure determination step of determining a disassembly procedure of the target product by calculating, on the basis of CAD data of the target product included in the product data and attribute data of a component constituting the target product, a disassembly path that is a movement route that does not interfere with other components for each component; and
a disassembly procedure manual creation step of creating a disassembly procedure manual on the basis of the determined disassembly procedure.

14. A disassembly procedure manual creation system comprising: a terminal device used by a product disassembler; and a disassembly procedure manual creation device, wherein
the terminal device displays a UI screen,
the disassembly procedure manual creation device includes
a UI control unit configured to receive information that is input to the UI screen from the product disassembler and designates a target product to be disassembled,
a target product search unit configured to identify the target product with reference to a product DB that manages product data related to products that may be targets of disassembly, and acquire, from the product DB, the product data corresponding to the identified target product,
a disassembly procedure determination unit configured to determine a disassembly procedure of the target product by calculating, on the basis of CAD data of the target product included in the product data and attribute data of a component constituting the target product, a disassembly path that is a movement route that does not interfere with other components for each component, and
a disassembly procedure manual creation unit that creates a disassembly procedure manual on the basis of the determined disassembly procedure, and
the UI control unit displays the created disassembly procedure manual on the UI screen.
